(19) United States
(12) Patent Application Publication
(10) Pub. No.: US 2024/0322656 A1
(43) Pub. Date: Sep. 26, 2024

(54) DIODE CARRIER ARRANGEMENT, OVERVOLTAGE PROTECTION DEVICE WITH THE SAME, MOTOR VEHICLE COMPONENT WITH THE SAME AND MANUFACTURING METHOD FOR A DIODE CARRIER ARRANGEMENT

(71) Applicant: MAHLE International GmbH, Stuttgart (DE)

(72) Inventor: Janko Cotar Mlakar, Dornberk (SI)

(21) Appl. No.: 18/209,322

(22) Filed: Jun. 13, 2023

(30) Foreign Application Priority Data
Jun. 13, 2022 (EP) 22178579.3

(51) Int. Cl. H02K 11/26; H05K 5/02; H05K 5/03

(52) U.S. Cl. CPC H02K 11/26; H05K 5/0247; H05K 5/03

(57) ABSTRACT

A diode carrier arrangement for an electric machine is disclosed. The diode carrier arrangement includes diodes, a rail arrangement including metal rails, a metal plate, and an enclosure. The enclosure and a first metal rail delimit a first diode receptacle for receiving a diode, and the enclosure and the metal plate delimit a second diode receptacle for receiving a diode. The diodes are clamped in the respective diode receptacles via the enclosure onto the first metal rail and the metal plate.

### CROSS-REFERENCE TO RELATED APPLICATIONS

This application claims priority to European Patent Application No. EP22178579.3, filed on Jun. 13, 2022, the contents of which is hereby incorporated by reference in its entirety.

### TECHNICAL FIELD

The invention relates to a diode carrier arrangement. The invention, in particular, relates to an overvoltage protection with a diode carrier arrangement, further in particular to a motor vehicle component with a diode carrier arrangement or to an overvoltage protection device and, further, in particular to a manufacturing method for a diode carrier arrangement.

### BACKGROUND

A diode carrier arrangement of the type mentioned at the outset is described for example in U.S. Pat. No. 3,876,926 A. These are usually installed as individual component in the engine compartment of a motor vehicle and cabled to an electric machine so that a corresponding installation space has to be reserved there for it and cabling. Disadvantageous in this is that because of this the installation space of the engine compartment that is already greatly limited anyway is reduced although as large as possible an available installation space is desired.

The object of the invention consists in providing an improved or at least another embodiment of a diode carrier arrangement. In particular an attempt is to be made to state an overvoltage protection device with a diode carrier arrangement and a motor vehicle component with a diode carrier arrangement or an overvoltage protection device. Furthermore, a manufacturing method for a diode carrier arrangement is to be provided.

With the present invention, this object is solved in particular through the subjects of the independent claim(s). Advantageous embodiments are the subject of the dependent claim(s) and of the description.

### SUMMARY

For solving the object, a diode carrier arrangement for an electric machine, in particular a generator, further in particular an alternator of a motor vehicle, is proposed which comprises at least two diodes, which are each equipped with a diode body, at least one electrical connection contact pin arranged thereon for electrically contacting a respective diode and an electrical connection contact formed by the diode body or formed integrally with the diode body for electrically contacting a respective diode, a rail arrangement comprising two separate electrically conductive metal rails, at least one separate electrically conductive metal plate, an enclosure arranged on the rail arrangement and the at least one metal plate for holding the rail arrangement and the at least one metal plate, for example a moulded-on plastic enclosure. Here, the enclosure holds the at least one metal plate sandwich-like between the metal rails so that the at least one metal plate does not directly touch the metal rails, i.e. is contactless with respect to these, and flanked by the metal rails on both sides. It is substantial that the diode carrier arrangement according to the invention comprises at least one first diode receptacle delimited or formed by way of the enclosure and a first metal rail of these two metal rails for receiving a diode and at least one second diode receptacle delimited or formed by way of the enclosure and the at least one metal plate for receiving a diode. A first diode is inserted into the at least one first diode receptacle, wherein the said first diode with its at least one connection contact pin is integrally connected to the at least one metal plate in an electrically conductive manner, in particular soldered or welded, and by way of the enclosure clamped onto the first metal rail so that its connection contact and/or its diode body is contacted with the first metal rail electrically and in a thermally conductive manner. A second diode is inserted into the at least one second diode receptacle, wherein the said second diode with its at least one connection contact pin is integrally connected to a second metal rail of these two metal rails in an electrically conductive manner, in particular soldered or welded, and by way of the enclosure clamped onto the at least one metal plate so that its connection contact and/or its diode body is electrically and thermally conductively contacted with the at least one metal plate. By way of this, a diode carrier arrangement carrying at least two (in particular identical) diodes is provided, which can be integrated for example in an electric machine, in particular a generator, further in particular an alternator of a motor vehicle, as a result of which advantageously an installation space usually necessary for installing a diode carrier arrangement within an engine compartment of a motor vehicle can be saved and otherwise allocated.

In order to improve the heat conduction between a diode body of at least one diode and the first metal rail and/or the at least one metal plate, it can be practically provided that between the diode body of the at least one diode and the first metal rail and/or the at least one metal plate, heat-conducting paste or heat-conducting adhesive is introduced, which wets both the diode body of the at least one diode as well as the first metal rail and/or the at least one metal plate.

The said diodes can be realised, for example, by transient voltage suppressor diodes (so called TVS diodes). To the person skilled in the art the transient voltage suppressor diode is a protection diode designed to protect electronic circuits against transients and overvoltage threats. In particular, it is designed to absorb large amounts of energy (e.g. joules) in a very short period of time (e.g. milliseconds).

Practically it is provided that the at least one first diode receptacle and the at least one second diode receptacle are arranged on two sides of the diode carrier arrangement that are opposite to one another. Because of this, the first diode receptacles and second diode receptacles of the diode carrier arrangement can be relatively easily and briskly equipped with diodes since the diodes can be fed to the diode carrier arrangement from different sides. Furthermore, this results in a relatively compact design. Alternatively, the at least one first diode receptacle and the at least one second diode receptacle can be arranged on one same side of two sides of the diode carrier arrangement that are opposite to one another. This is advantageous, if additional ribbed heat sinks arranged on the first metal rail and/or the second metal rail. This can be important for heat dissipation purposes.

Further practically it is provided that the at least one first diode receptacle and the at least one second diode receptacle are equal in size. Because of this, identical diodes, i.e. diodes of identical size, can be inserted into the respective diode receptacles. Because of this, the installation of the diode carrier arrangement is possible without major effort since the diodes need not be assigned to specific diode receptacles but instead can be inserted into any diode receptacles.

Practically it is provided that the at least one first diode receptacle is arranged in a first plane or at least two first diode receptacles define a first plane. Furthermore, the at least one second diode receptacle can be arranged in a second plane or at least two second diode receptacles define a second plane. Further, the first plane and the second plane can be arranged parallel and/or offset to one another. Because of this, an advantageous embodiment is stated, by way of which the metal rails and the metal plates of the diode carrier arrangement can be relatively easily connected to one another in an electrically conductive and/or thermally conductive manner.

Further practically it is provided that the first metal rail and/or the second metal rail and/or the at least one metal plate are each realised integrally and/or through a flat body each. Furthermore, the first diode arranged in the at least one first diode receptacle can be electrically connected in series with the second diode arranged in the at least one second diode receptacle. Here, it can be practically provided that the first diode arranged in the at least one first diode receptacle is electrically connected in series with the second diode arranged in the at least one second diode receptacle and, with respect to at least one further first diode and at least one further second diode, which are arranged in a further first diode receptacle and a further second diode receptacle respectively and are electrically connected in series with one another, are electrically connected in parallel. Because of this, the metal rails and/or the metal plates can be cost-effectively provided in large quantities, so that the diode carrier arrangement altogether can be realised cost-effectively.

Practically it is provided that the enclosure is formed by a one-piece contiguous component or by separate segments. Because of this, the enclosure of the diode carrier arrangement can be realised cost-effectively and in particular as an injection-moulded part.

Further practically it is provided that the first metal rail in its main extension defines a main axis and is zoned into three contiguous flat rail portions extending in the direction of the main axis. Here, the first metal rail can comprise two integral bending portions, which are each arranged with respect to the main axis between two rail portions and integrally connect these to one another, wherein the bending portions are deformed or bent for example as part of the installation of the diode carrier arrangement on an electric machine, in particular a generator, further in particular an alternator of a motor vehicle transversely to the main axis, so that the rail portions are tilted to one another by a predetermined or predeterminable bending angle. It is practical when the bending angle amounts to maximally 45° and/or the bending angle amounts to minimally 5° or is smaller than 5°. Here it can be also provided in particular that a width of the bending portions, which is oriented transversely with respect to the main axis, is smaller than a width of the rail portions that are likewise oriented transversely with respect to the main axis. In this connection it can also be provided that a width of the bending portions, which are oriented transversely with respect to the main axis, amounts to maximally 50% or particularly less than 25% or more particularly less than 10% of a width of the rail portions likewise oriented transversely with respect to the main axis, and/or that a width of the bending portions which are oriented transversely with respect to the main axis, amounts to at least 25% of a width of the rail portions likewise oriented transversely with respect to the main axis. Because of this, the first metal rail can be deformed or bent with simple means, for example manually by hand, in particular transversely to its main direction, wherein merely the said bending portions plastically deform permanently while the said rail portions remain flat. Initially, this has the advantage that the diode carrier arrangement or the first metal rail as part of its installation can be adapted relatively easily to curved or complex contours of an electric machine, in particular a generator, further in particular an alternator of a motor vehicle. Furthermore, this has the advantage that the rail portions reserved for the arrangement of the diodes are flat and thus remain easily equippable with diodes. Optionally, the bending portions could be divided each in two separate bending subportions which are easier to bend. Particularly, in that case the width of each bending subportion would be less than 25% of the width of the rail portions.

Practically, the term “zoning” is also understood as “subdividing” by the person skilled in the art.

Practically it is provided that the at least one first diode receptacle is delimited or formed by a flat rail portion of the first metal rail and by a first transverse support element of the enclosure. Here, the first transverse support element can elastically clamp the first diode inserted into the at least one first diode receptacle onto the respective rail portion of the first metal rail. Further it can be provided that the at least one second diode receptacle is delimited or formed by the at least one metal plate and by a second transverse support element of the enclosure, wherein, practically, the second transverse support element elastically clamps the second diode inserted into the at least one second diode receptacle onto the at least one metal plate. By way of this, preferred embodiments for diode receptacles are stated. It is practical when the said first and second transverse support elements of the enclosure are each embodied bar-shaped and/or have a rectangular cross-section. It is practical, furthermore, when the enclosure besides the transverse support elements has so-called support elements which are directly arranged on the said metal rails and the at least one metal plate, are orthogonally oriented with respect to the transverse support elements and are embodied integrally with the same.

Further practically it is provided that the rail arrangement comprises a connection contact tab arranged on the first metal rail of these two metal rails, which is equipped for soldering on or welding on, in particular by resistance welding or laser welding, of a power supply conductor of an electric machine. In particular, the said connection contact tab may can be curved and/or cranked or realise an offset connection contact tab. Further it can be provided that the rail arrangement comprises a further, in particular offset, connection contact tab arranged on the second metal rail of these two metal rails, which is equipped for soldering on or welding on a neutral conductor of an electric machine, in particular by resistance welding. Practically, the connection contact tab and the further connection contact tab are arranged on two sides of the diode carrier arrangement that are opposite to one another. Because of this, the diode carrier arrangement has practical electrical connecting tabs by way of which its diodes can be supplied with electric energy. Practically, the connecting tab and the further connecting tab can be arranged on a common side of the diode carrier arrangement, as a result of which the electrical installation of these on an electric machine is simplified since the connecting tab and the further connecting tab are reachable from a side by an installer. Practically, the connecting tab and/or the further connecting tab can be formed integrally with the first metal rail or with the second metal rail.

Practically it is provided that the enclosure comprises fastening projections for fastening the diode carrier to an electric machine, in particular a generator, further in particular an alternator of a motor vehicle. Further, the fastening projections can each be equipped with a central opening for fastening means, in particular a fastening screw. By way of this, the diode carrier arrangement can be fastened to an electric machine with simple means, for example with fastening screws.

Further practically it is provided that the enclosure is produced from a thermoplastic material, for example from an injection-mouldable polyamide 66 (PA66), from polybutylene terephthalate (PBT), polyethylene terephthalate (PET) or from a similar injection-mouldable plastic material. Instead it can be provided that the enclosure is produced from a thermoplastic material, for example from an injection-mouldable polyamide 66 (PA66), from polybutylene terephthalate (PBT), polyethylene terephthalate (PET) or from a similar injection-mouldable plastic as well as a filling material, in particular a glass or mineral fibre filling material. Because of this, the enclosure of the diode carrier arrangement can be realised cost-effectively and in particular as an injection-moulded part since the defined plastic materials all exhibit a relatively favourable suitability for injection moulding. Practically, a filling material can be admixed to the plastic material used in order to mechanically reinforce the enclosure.

Practically it is provided that the first metal rail and/or the second metal rail are realised by punched parts and/or are punched out of a thin conductive metal sheet. Furthermore, it can be provided that the first metal rail and/or the second metal rail are realised from copper material, brass material, bronze material or other conductive metal materials. Furthermore, the at least one metal plate can be realised through a punched part and/or be punched out of a thin conductive metal sheet. It can also be provided that the at least one metal plate is realised from copper material, brass material, bronze material or other conductive metal materials. Because of this, the metal rails and/or the metal plates can be provided cost-effectively and in large quantities so that the diode carrier arrangement can be realised altogether cost-effectively. By copper material, the invention means for example pure copper or copper alloys, in particular brass material or bronze material. Such metal rails and/or metal plates additionally have the major advantage that they have a relatively good electrical conductivity and at the same time also a good thermal conductivity. Because of this, the diodes can be outstandingly connected for example to an electrical supply network of a generator or of an alternator. Furthermore, heat energy incurred on the diodes during the operation of the diode carrier arrangement can be efficiently discharged.

Another basic idea of the invention, which can be realised additionally or alternatively to the basic idea mentioned further up can consist in providing an overvoltage protection device for an electric machine, in particular a generator, further in particular an alternator of a motor vehicle, which comprises at least one diode carrier arrangement according to the preceding description. Here, the diodes of the diode carrier arrangement can be configured to or practically equipped in order to protect the electric machine from a supply voltage also referred to as overvoltage, which, because of a fault increases above the rated voltage of the electric machine. By way of this, an advantageous overvoltage protection device for an electric machine is provided. The overvoltage protection device can be space-savingly arranged for example within the electric machine and there electrically contacted with the electric machine.

Another basic idea of the invention, which can be realised additionally or alternatively to the basic idea mentioned further up can consist in providing a motor vehicle component, in particular an electric machine, in particular a generator, further in particular an alternator of a motor vehicle which comprises at least one diode carrier arrangement arranged within the motor vehicle component and electrically contacted with the same according to the preceding description or comprises at least one overvoltage protection device arranged within the motor vehicle component and electrically contacted with the same for an electric machine according to the preceding description. The said motor vehicle component can optionally comprise a main body and a protective cover that can be placed or is placed on the same, which on a cover inside comprises a clamping device which is equipped for receiving and clamping the diode carrier arrangement or the overvoltage protection device. Practically, the clamping device comprises clamping projections forming or delimiting a clamping receptacle which can be embodied for example integrally with the protective cover. In the assembled state of the motor vehicle component, the diode carrier arrangement or the overvoltage protection device is inserted into the clamping receptacle, wherein the clamping projections clamp and/or snap into the enclosure of the diode carrier arrangement or the overvoltage protection device, as a result of which the diode carrier arrangement or the overvoltage protection device is fixed on the protective cover. Because of this, in particular own movements of the diode carrier arrangement or of the overvoltage protection device as a consequence of vibrations occurring on the protective cover can be prevented, which for example contributes to the noise reduction. Altogether, an advantageous motor vehicle component, in particular an electric machine, with a diode carrier arrangement or an overvoltage protection device is thereby stated, wherein through the arrangement of the diode carrier arrangement or of the overvoltage protection device within the motor vehicle component for example an installation space usually necessary for installing a diode carrier arrangement or the overvoltage protection device within an engine compartment of a motor vehicle can be saved and otherwise allocated.

Furthermore, a motor vehicle component, in particular an electric machine, further in particular a generator, further in particular an alternator of a motor vehicle, can be provided, the motor vehicle component comprising a diode carrier arrangement, for example according to the above description, wherein the diode carrier arrangement is assembled with a protective cover of the motor vehicle component to form a subassembly, wherein the diode carrier arrangement is pressed against the protective cover and fixed to the protective cover by clamping, for example by fastening projections of the diode carrier arrangement or by friction with pressing into slits and the power supply and the ground supply connectors of the protective cover are soldered or welded to the power and ground connectors of the diode carrier arrangement. For example, the subassembly can be formed only after the diode carrier arrangement is inserted-pressed against the protective cover and also the connectors are welded or soldered. This way the diode carrier arrangement can be on one side fixed and secured with plastic projections and welded conductors and on the other side it can become fixed only after being screwed to the main body of the motor vehicle together with the protective cover. The protective cover further comprising a cover power supply conductor connector configured for serving as a power supply for the diode carrier arrangement and a cover neutral conductor connector configured for serving as a ground supply for the diode carrier arrangement, wherein the said subassembly is assembled to a main body of the motor vehicle component by fastening means, preferably screws, wherein the fastening means, preferably the screws, go through the fastening projections of the diode carrier arrangement and fastening projections of protective cover. Thereby a preferred embodiment is provided.

Another basic idea of the invention, which can be realised additionally or alternatively to the basic idea mentioned further up can consist in stating a manufacturing method for a diode carrier arrangement. To this end, the following steps are:
1) providing a punched blank, which comprises a first metal rail, a second metal rail and between the first metal rail and the second metal rail at least one metal plate, wherein the at least one metal plate is realised by way of installation aid ribs is integrally connected to the first metal rail and integrally connected to the second metal rail of a metallic plate material, which is optionally realised by copper material, brass material, bronze material or other conductive metal materials by punching out, and
2) adapting the two metal rails (4, 18) to a predetermined contour of an electric machine (46) by deforming or bending, and
3) providing an enclosure for holding the two metal rails and the at least one metal plate of a thermoplastic material, for example of an injection-mouldable polyamide 66 (PA66), from polybutylene terephthalate (PBT), polyethylene terephthalate (PET) or from a similar injection-mouldable plastic material, and/or a filling material, in particular a glass or mineral fibre filling material, and providing at least one first diode receptacle for receiving a diode and at least one second diode receptacle for receiving a diode, in that the provided punched blank, subject to forming or delimiting the at least one first diode receptacle and the at least one second diode receptacle, is over-moulded, for example by means of an injection moulding machine, and
4) severing or cutting off of the installation aid ribs (74) by punching, and
5) inserting a first diode into the at least one first diode receptacle, so that this first diode is clamped onto the metal rail by way of the enclosure so that the first metal rail, in particular its connection contact and/or its diode body, is electrically as well as thermally conductively contacted with the first metal rail, and electrically conductive integral connecting of the at least one connection contact pin of this first diode with the at least one metal plate, in particular soldering-on or welding-on, and
6) inserting a second diode into the at least one second diode receptacle, so that this second diode is clamped onto the at least one metal plate by way of the enclosure, so that the said metal plate, in particular its connection contact and/or its diode body is electrically and thermally conductively contacted with the at least one metal plate, and electrically conductive integral connecting of the at least one connection contact pin of this second diode with a second metal rail of these two metal rails, in particular soldering-on or welding-on.

By way of this, a preferred manufacturing method for a diode carrier arrangement is stated, by way of which a diode carrier arrangement can be provided for example cost-effectively.

In summary it remains to note: the present invention preferentially relates to a diode carrier arrangement comprising diodes, a rail arrangement comprising metal rails, at least one metal plate and an enclosure for holding the rail arrangement and/or the at least one metal plate. It is substantial that by way of the enclosure and a first metal rail of these metal rails a first diode receptacle for receiving diodes and by way of the enclosure and the at least one metal plate, a second diode receptacle for receiving diodes is delimited. In the diode receptacle, diodes are inserted and by way of the enclosure clamped onto the first metal rail or the at least one metal plate. The invention relates in particular to an overvoltage protection device with a diode carrier arrangement, further in particular to a motor vehicle component with a diode carrier arrangement or to an overvoltage protection device and further in particular to a manufacturing method for a diode carrier arrangement.

Further important features and advantages of the invention are obtained from the dependent claims, from the drawings and from the associated figure description by way of the drawings.

It is to be understood that the features mentioned above and still to be explained in the following cannot only be used in the respective combination stated but also in other combinations or by themselves without leaving the scope of the present invention.

Preferred embodiments of the invention are shown in the drawings and are explained in more detail in the following description, wherein same reference numbers relate to same or similar or functionally same components.

### BRIEF DESCRIPTION OF THE DRAWINGS

It Shows, in Each Case Schematically

FIG. 1 a perspective view of a diode carrier arrangement according to a preferred embodiment,

FIG. 2 the diode carrier arrangement from FIG. 1 in a perspective view looking in the direction of an arrow II entered in FIG. 1,

FIG. 3 the diode carrier arrangement from FIG. 1 in a plan view looking in the direction of an arrow III entered in FIG. 1,

FIG. 4 in a greatly simplified sectional view the diode carrier arrangement from FIG. 1 cut open along a plane indicated in FIG. 1 with dashed line looking in the direction of an arrow IV entered there,

FIG. 5 in a perspective view a punched blank for producing a diode carrier arrangement 1 according to FIGS. 1 to 4 approximately looking in the direction of an arrow V entered in FIG. 1,

FIG. 6 a perspective view of a motor vehicle component realised by an electric machine with a diode carrier arrangement according to FIGS. 1 to 5 and finally,

FIG. 7 a perspective view of the motor vehicle component from FIG. 6, wherein a protective cover of the motor vehicle component is lifted off and turned upside down so that a cover inside of the protective cover and a diode carrier arrangement arranged there is noticeable.

### DETAILED DESCRIPTION

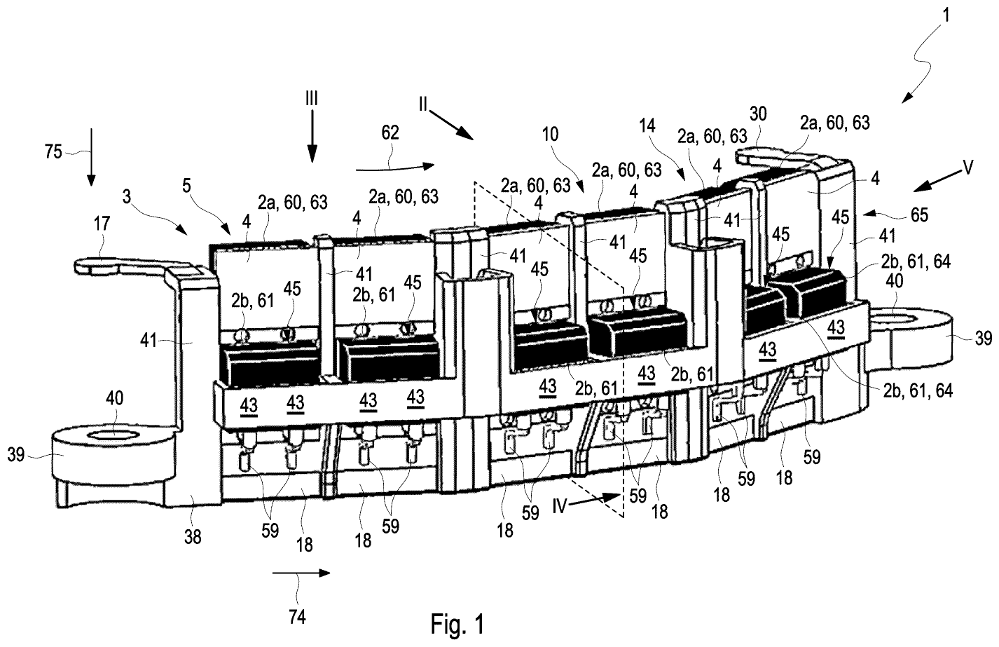

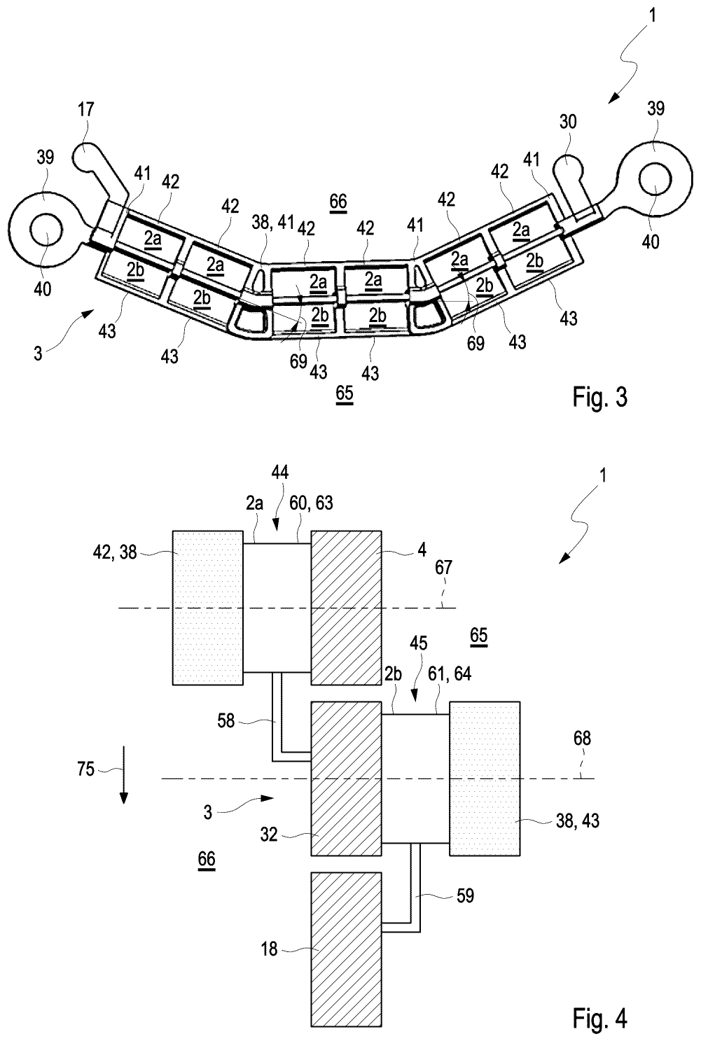

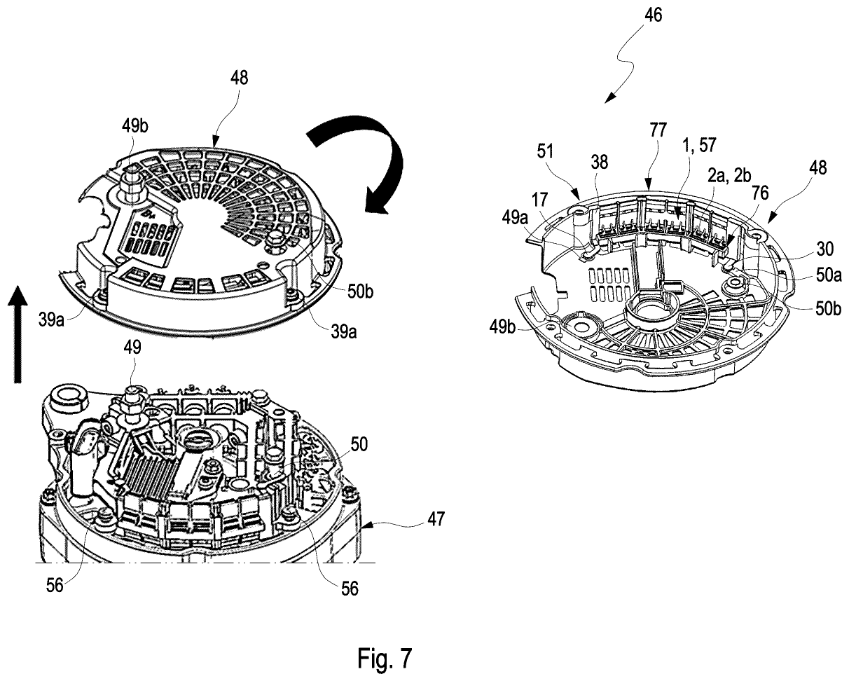

FIGS. 1 to 4 show a preferred exemplary embodiment of a diode carrier arrangement designated altogether with the reference number 1 for a motor vehicle component 46 illustrated in FIGS. 6 and 7 realised exemplarily by an electric machine 46, which alternatively could also be realised by a generator and further in particular by an alternator of a motor vehicle.

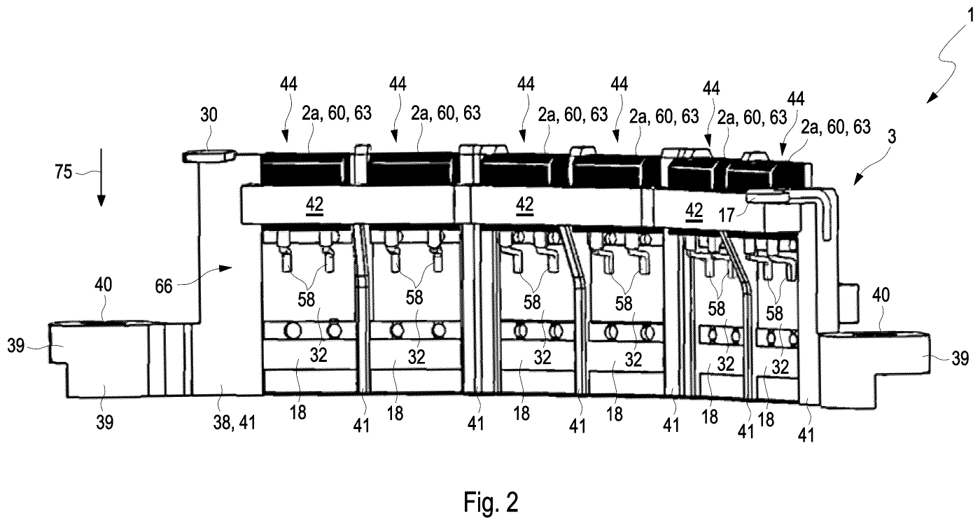

FIGS. 1 and 2 each show the diode carrier arrangement 1 in a perspective view, namely looking from the front (FIG. 1) or from the back (FIG. 2). The diode carrier arrangement 1 comprises multiple, altogether twelve diodes 2a, 2b of the same size and shape, which are each equipped with a diode body 60, 61, each with two electrical connection contact pins 58, 59 arranged on the respective diode body 60, 61 for electrically contacting a respective diode 2a, 2b and each with an electrical connection contact 63, 64 formed by the respective diode body 60, 61 or integrally formed with the respective diode body 60, 61 for electrically contacting a respective diode 2a, 2b. For example, the diodes 2a, 2b are realised by commercially available transient voltage suppressor diodes, so called TVS diodes.

Furthermore, the diode carrier arrangement 1 comprises a rail arrangement 3, the exemplarily two separate electrically conductive metal rails 4, 18, namely a first metal rail 4 and a second metal rail 18, as well as an offset connection contact tab 17 arranged integrally on the first metal rail 4 and configured for soldering-on or welding-on a power supply conductor 49 of a motor vehicle component 46 or a cover power supply conductor connector 49a of a protective cover 48 of the motor vehicle component 46 or an electric machine 46 and an offset further connection contact tab 30 arranged integrally on the second metal rail 18 and configured for soldering-on or welding-on a neutral conductor 50 of a motor vehicle component 46 or a cover neutral conductor connector 50a of the protective cover 48 of the motor vehicle component 46 or of an electric machine 46. The connection contact tabs 17, 30 are exemplarily arranged on sides of the diode carrier arrangement 1 that are opposite to one another. The first metal rail 4 and the second metal rail 18 are each embodied flat, for example each formed by a flat body, and for example realised as punched parts, which with the help of a punching tool are punched out of a rolled or coiled plate material of copper material, brass material, bronze material or another conductive metal material. The first metal rail 4 defines in its main extension a main axis 62, the second metal rail 18 defines in its main extension a further main axis 74. The first metal rail 4 and the second metal rail 18 are arranged in parallel with respect to the main axes 62, 74 and are spaced apart from one another transversely with respect to their main axes 62, 74, so that the first metal rail 4 and the second metal rail 18 do not directly touch and as a result of which between them a receptacle for metal plates 32 explained in the following is delimited. Practically, the main axes 62, 74 respectively the first metal rail 4 and the second metal rail 18 can be bent.

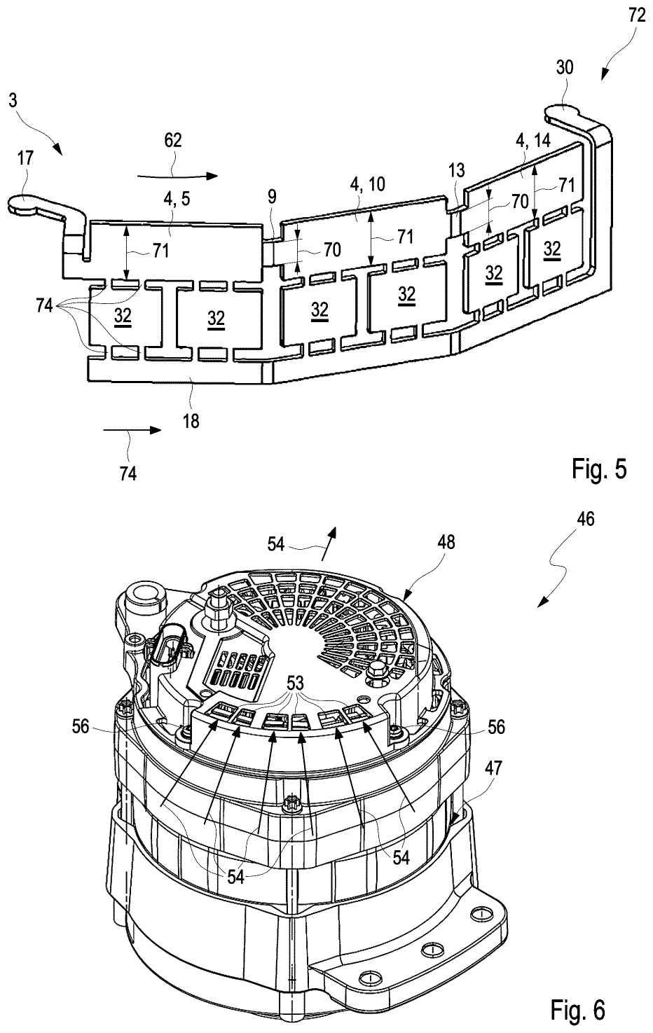

The first metal rail 4 is zoned, i.e. subdivided, into three contiguous flat rail portions 5, 10, 14 arranged one behind the other in the direction of the main axis 62 extending in the direction of the main axis 62, see in particular FIGS. 1 and 5. To achieve better cylindrical shape or curved shape of the diode carrier arrangement 1, the first metal rail 4 is, for example, subdivided into six flat rail portions ideally-one for each diode 2a. With this design the first metal rail 4 is simplified and some bending is saved. Also the insertion of the diodes 2a and the welding of the diodes 2a, i.e. their respective diode bodies 60, 61, on that flat rail portions is simplified. Depending on needs and available space, the first metal rail 4 could also be subdivided in more or less flat portions. The first metal rail 4, further, comprises two integral bending portions 9. 13, see FIG. 5, which are each connected with respect to the main axis 62, between the rail portions 5, 10, 14 and integrally connect the same with one another. The bending portions 9, 13 are or can be deformed or bent as part of the installation of the diode carrier arrangement 1 on a motor vehicle component 46 or an electric machine 46 transversely to the main axis 62, as a result of which the rail portions 5, 10, 14 are tilted to one another by a predetermined or predeterminable bending angle 69, so that the first metal rail 4 altogether has a bent contour. Practically, the second metal rail 18 is also deformed or bent according to the first metal rail 4 so that it also has a bent contour. Because of this, the first and second metal rail 4, 18 can be relatively easily and flexibly adapted as part of their installation on a motor vehicle component 46 or an electric machine 46 to curved or complex contours of the motor vehicle component 46 or the electric machine 46. It is practical in this connection when a width 70 of the bending portions 9, 13, see FIG. 5, which are oriented transversely, in particular perpendicularly with respect to the main axis, 62, is smaller than a width 71 of the rail portions 5, 10, 14 likewise oriented transversely, in particular perpendicularly with respect to the main axis 62. By way of this it can be ensured that when adapting the first metal rail 4 to a contour of the motor vehicle component 46 or the electric machine 46, only the bending portions 9, 13 deform or bent while the rail portions 5, 10, 14 remain in their flat original form, so that the diodes 2a, 2b explained at the outset can be easily placed onto them with optimal electrical and thermal conductivity.

In addition, the diode carrier arrangement 1 comprises altogether six separate electrically conductive metal plates 32. These have purely exemplarily a rectangular or square outer contour each and are each embodied flat and for example realised as punched parts, which are punched out of a rolled or coiled plate material of copper material, brass material, bronze material or another conductive metal material with the help of a punching tool. The metal plates 32 are arranged in the said receptacle between the first metal rail 4 and the second metal rail 18 so that they do not directly touch the first metal rail 4 and the second metal rail 18 and are flanked by the metal rails 4, 18 on both sides, see in particular FIG. 4.

Besides the rail arrangement 3 and the metal plates 32, the diode carrier arrangement 1 comprises a monolithic enclosure 38 arranged on the rail arrangement 3, i.e. on the first metal rail 4, the second metal rail 18 and practically on the connection contact tabs 17, 30 and/or the said metal plates 32, which is equipped to hold the rail arrangement 3 and/or the said metal plates 32 and/or the diodes 2a, 2b. According to the present embodiment, the enclosure 38 is realised through a plastic enclosure 38 moulded onto the rail arrangement 3 and/or the said metal plates 32, which can be produced for example from a thermoplastic material, for example of an injection-mouldable polyamide 66 (PA66), from polybutylene terephthalate (PBT), polyethylene terephthalate (PET), or from a similar injection-mouldable plastic material, as well as optionally a filling material for stiffening, in particular a glass or mineral fibre filling material in order to realise a cost-effective manufacture of the enclosure 38 with relatively good strength and stiffness characteristics at the same time. In particular in FIGS. 1 to 3 it is noticeable that the enclosure 38, with respect to the main axes 62, 74, comprises support elements 41 arranged at a right angle and first and second transverse support elements 42, 43 which with respect to the main axes 62, 74 are arranged in parallel and fastening projections 39 arranged on two sides of the diode carrier arrangement 1 located opposite one another, for example in the neighbourhood of the connection contact tabs 17, 30 for fastening the diode carrier arrangement 1 to a motor vehicle component 46 or to an electric machine 46. As mentioned, the support elements 41, the first and second transverse support elements 42, 43 and the fastening projections 39 form a monolithic enclosure 38. Nevertheless, the enclosure 38 could also be embodied in segments. It should be mentioned, furthermore, that the said fastening projections 39 are each formed by a ring projection with a central opening 40 for fastening means, in particular a fastening screw 56. However, other fastening means or fastening measures are also conceivable by means of which the diode carrier arrangement 1 can be fastened to a motor vehicle component 46 or to an electric machine 46, for example snap-in connections, clamping connections or bonded connections are conceivable. With respect to FIGS. 1 and 2 it should be noted that the enclosure 38 optionally also holds the said metal plates 32, so that it is arranged, sandwich-like and contact-free between the metal rails 4, 18 as mentioned.

It is substantial that the diode carrier arrangement 1 comprises at least one first diode receptacle 44 delimited or formed by way of the enclosure 38 and of the first metal rail 4 for receiving diodes 2a, 2b and at least one second diode receptacle 45 delimited or formed by way of the enclosure 38 and of the at least one metal plate 32 for receiving diodes 2a, 2b. According to the present embodiment, six first diode receptacles 44 arranged in series in the direction of the main axis 62 are exemplarily provided for first diodes 2a. Here, the first diode receptacles 44 are each delimited by a flat rail portion 5, 10, 14 of the first metal rail 4 and by a first transverse support element 42 of the enclosure 38. In each first diode receptacle 44, a first diode 2a is inserted with its connection contact pins 58 upfront in an extension direction 75, in the manner that a respective first transverse support element 42 clamps a respective inserted first diode 2a, i.e. its connection contact 63 and/or its diode body 60 elastically onto the respective rail portion 5, 10, 14 of the first metal rail 4, wherein the connection contact pins 58 of a respective first diode 2a are arranged on a metal plate 32 of these six metal plates 32. Because of this, the respective connection contact 63 and/or the diode body 60 of a first diode 2a are electrically and thermally conductively contacted with the first metal rail 4. In order to optimise the electrical and/or thermal contacting of the first diodes 2a with the first metal rail 4, heat conducting paste or heat conducting adhesive can be practically connected in between. The said connection contact pins 58 of the first diodes 2a can be or are integrally connected to the said metal plates 32 in an electrically conductive manner in particular by soldering or welding, in particular resistance welding. Furthermore, six second diode receptacles 45 for second diodes 2b arranged in series in the direction of the main axis 62 are provided according to the present embodiment. Here, the second diode receptacles 45 are each delimited by a flat metal plate 32 and by a second transverse support element 43 of the enclosure 38. In each second diode receptacle 45, a second diode 2b is inserted with its connection contact pins 59 upfront in the extension direction 75, in the manner that a respective second transverse support element 43 elastically clamps a respective inserted second diode 2b, i.e. its connection contact 64 and/or its diode body 61, onto the respective metal plate 32, wherein the connection contact pins 59 of a respective second diode 2b are arranged on the second metal rail 18. Because of this, the connection contact 64 and/or the diode body 61 of a respective second diode 2b is electrically and thermally conductively contacted with a respective metal plate 32. In order to optimise the electrical and/or thermal contacting of the second diodes 2b with the respective metal plate 32, heat-conducting paste or heat-conducting adhesive can be practically connected in between. The said connection contact pins 59 of the second diodes 2b can or are integrally connected to the second metal rail 18 in an electrically conductive manner for example by soldering or welding, in particular resistance welding. By way of this configuration, the first metal rail 4 and the second metal rail 18 are electrically conductively connected to one another via at least one first diode 2a, at least one metal plate 32 and at least one second diode 2b. By way of this it is provided, further, that a first diode 2a is assigned to a second diode 2b or vice versa, as a result of which an electrical series connection of these diodes 2a, 2b is realised in a branch. Adjacent branches, i.e. the diodes 2a, 2b of adjacent diode receptacles 44, 45 electrically connected in series are practically arranged electrically connected in parallel to one another. In FIGS. 1 and 2 it is noticeable, furthermore, that the first diode receptacles 44 and the second diode receptacles 45 are arranged on two sides 65, 66 of the diode carrier arrangement 1 that are opposite to one another and identical in size. Because of this, identical diodes 2a, 2b, i.e. diodes of the same size can be inserted into the respective diode receptacles 44, 45, wherein the installation is relatively simple since the diodes 2a, 2b can be fed to the diode carrier arrangement 1 from different sides 65, 66 and in a common insertion direction 75. Furthermore, it is noticeable for example in FIG. 4 that the first diode receptacles 44 are arranged in a first plane 67 indicated by a dashed line or define the same and that the second diode receptacles 45 are arranged in a further second plane 68 indicated by a dashed line or define the same, wherein the first plane 67 and the second plane 68 are parallel and offset to one another.

FIG. 5 shows in a perspective view a punched blank 72 which can be utilised in the production of a diode carrier arrangement 1 from FIGS. 1 to 4. The punched blank 72 forms an integral unit and includes the first metal rail 4, the second metal rail 18 and, between the first metal rail 4 and the second metal rail 18, the explained six metal plates 32. The latter are, in the state of the punched blank 72 as delivered, initially integrally connected to the first metal rail 4 and to the second metal rail 18 by way of installation aid ribs 74, which in FIG. 5 are provided with reference number for only one metal plate 32. Because of this, the handling of the punched blank 72 is relatively simple and handy, since metal rails 4, 18 and metal plates 32 form a unit. The punched blank 72 is realised for example with the help of a punching tool from a metallic plate material which is optionally a copper material, brass material, bronze material or other conductive metal material. As soon as the punched blank 72 has been stabilised by injection moulding-on the enclosure 38, the installation aid ribs 74 can be severed, for example by punching.

FIGS. 6 and 7 show a preferred exemplarily embodiment of a motor vehicle component marked as a whole with the reference number 46, which is realised by an electric machine 46 here. It comprises at least one diode carrier arrangement 1 according to FIGS. 1 to 4 arranged within the motor vehicle component 46 and electrically contacted with the same. In this case, the diode carrier arrangement 1 is provided as overvoltage protection device 57, wherein its first and second diodes 2a, 2b are equipped in order to protect the electric machine 46 from a supply voltage also referred to as overvoltage, which, because of an internal or external fault, rises above the rated voltage of the electric machine 46. The motor vehicle component 46 exemplarily comprises a main body 47 and a protective cover 48, preferably a cover member, that can be placed or is placed onto the same and can be releasably fixed to the main body 47 by way of fastening screws 56. The protective cover 48 has on a cover inside 77 a clamping device 51 which is equipped for receiving and clamping the diode carrier arrangement 1 or the overvoltage protection device 57 on the protective cover 48. Practically, the clamping device 51 comprises clamping projections 52 forming or delimiting a clamping receptacle 76, which are embodied for example integrally with the protective cover 48. In the assembled state of the motor vehicle component 46, the diode carrier arrangement 1 or the overvoltage protection device 57 is inserted into the clamping receptacle 76, wherein the clamping projections 52 of the clamping device 51 clamp and/or snap into the enclosure 38 of the diode carrier arrangement 1 or the overvoltage protection device 57, as a result of which the diode carrier arrangement 1 or the overvoltage protection device 57 is fixed to the protective cover 48. Because of this, in particular own movements of the diode carrier arrangement 1 or of the overvoltage protection device 57 as a consequence of vibrations occurring on the protective cover 48 can be prevented, which contributes for example to the reduction of noise. As mentioned above, the main body 47 comprises a power supply conductor 49 and a neutral conductor 50 which are electrically contacted with the first connection contact tab 17 respectively the further connection contact tab 30 of the diode carrier arrangement 1 or of the overvoltage protection device 57, when the protective cover 48 equipped with the diode carrier arrangement 1 or the overvoltage protection device 57 is installed on the main body 47. It is provided that the protective cover 48 comprising a cover power supply conductor connector 49a configured for serving as a cover side power connector supply for the connection contact tab 17 of the diode carrier arrangement 1 and a cover neutral conductor connector 50a configured for serving as a cover side ground connector supply for the connection contact tab 30 of the diode carrier arrangement 1. Besides the aforementioned cover power supply conductor connector 49a and cover neutral conductor connector 50a the protective cover 48 further comprising two main connection connectors 49b, 50b for electrically connecting with the power supply conductor 49 respectively the neutral conductor 50 of said main body 47. It must also be mentioned, that the cover power supply conductor connector 49a is electrically conductive connected via a not shown cover connector line to the first main connection connector 49b and the cover neutral conductor connector 50a is, in the same way, electrically conductive connected to the second main connection connector 50b. For instance, the cover power supply conductor connector 49a, the cover neutral conductor connector 50a, the first main connection connector 49b and the second main connection connector 50b are integrally overmoulded into the protective cover 48 to form an uniform unit. Preferably, the protective cover 48 is therefore made of a plastic material, for example an injection moldable plastic material. In the assembled state, the diode carrier arrangement 1 is assembled, for example clamped, with the protective cover 48 in such a way that the connection contact tab 17 of the diode carrier arrangement 1 is in electrically contact with the cover power supply conductor connector 49a and the connection contact tab 30 of the diode carrier arrangement 1 is in electrically contact with the cover neutral conductor connector 50a. Preferably, the said connection tabs 17, 30 are each welded to the cover power supply conductor 49a respectively to the cover neutral conductor 50a. The protective cover 48 is assembled to the main body 47 of the motor vehicle component by fastening means, preferably fastening screws. Preferably the fastening screws go through the fastening projections 39 of the diode carrier arrangement 1 and fastening projections 39a of the protective cover 48.

The protective cover 48, furthermore, has ventilation openings designated with reference number 53, see in particular FIG. 6, by way of which a cooling airstream 54 of cooling air indicated by arrows there flows into the motor vehicle component 46 and cools the diode carrier arrangement 1 or the overvoltage protection device 57.

1. A diode carrier arrangement for an electric machine, comprising:
at least two diodes, which that are each equipped with a diode body and with at least one electrical connection contact pin arranged thereon for electrically contacting a respective diode and an electrical connection contact provided by the diode body or integrally formed with the diode body for electrically contacting a respective diode,
a rail arrangement including two separate electrically conductive metal rails,
at least one separate electrically conductive metal plate,
an enclosure arranged on the rail arrangement and the at least one metal plate for holding the rail arrangement and the at least one metal plate,
wherein the enclosure holds the at least one metal plate sandwich-like between the two metal rails so that the at least one metal plate does not directly touch the two metal rails and is flanked by the two metal rails,
at least one first diode receptacle delimited or formed by the enclosure and a first metal rail of the two metal rails for receiving a first diode of the at least two diodes and at least one second diode receptacle delimited or formed by the enclosure and the at least one metal plate for receiving a second diode of the at least two diodes,
wherein the first diode is inserted into the at least one first diode receptacle and is integrally connected with its at least one connection contact pin to the at least one metal plate in an electrically conductive manner and via the enclosure is clamped onto the first metal rail so that its connection contact is contacted to the first metal rail electrically and thermally conductively,
wherein the second diode is inserted into the at least one second diode receptacle, with its at least one connection contact pin integrally connected in an electrically conductive manner to a second metal rail of the two metal rails and via the enclosure is clamped onto the at least one metal plate so that its connection contact and/or its diode body is electrically contacted with the at least one metal plate in a thermally conductive manner.

2. The diode carrier arrangement according to claim 1, wherein:
the at least one first diode receptacle and the at least one second diode receptacle are arranged on two sides of the diode carrier arrangement that are opposite to one another, or
the at least one first diode receptacle and the at least one second diode receptacle are arranged on one same side of two sides of the diode carrier arrangement that are opposite to one another.

3. The diode carrier arrangement according to claim 1, wherein the at least one first diode receptacle and the at least one second diode receptacle are identical in size.

4. The diode carrier arrangement according to claim 1, wherein at least one of:
the at least one first diode receptacle is arranged in a first plane or at least two first diode receptacles define a first plane,
the at least one second diode receptacle is arranged in a second plane or at least two second diode receptacles define a second plane, and
the first plane and the second plane are parallel to one another and/or offset to one another.

5. The diode carrier arrangement according to claim 1, wherein at least one of:
the first metal rail and/or the second metal rail and/or the at least one metal plate are each realised integrally and/or by a flat body each,
the first diode arranged in the at least one first diode receptacle are electrically connected in series with the second diode arranged in the at least one second diode receptacle, and
the first diode arranged in the at least one first diode receptacle are electrically connected in series with the second diode arranged in the at least one second diode receptacle and with respect to at least one further first diode and at least one further second diode, which are arranged in a further first diode receptacle or a further second diode receptacle and are electrically connected in series with one another, are electrically connected in parallel.

6. The diode carrier arrangement according to claim 1, wherein the enclosure is formed by a one-piece contiguous component or by separate segments.

7. The diode carrier arrangement according to claim 1, wherein:
the first metal rail in its main extension defines a main axis and is zoned into three contiguous flat rail portions extending in a direction of the main axis,
wherein the first metal rail comprises two integral bending portions, which with respect to the main axis are each arranged between two rail portions of the three rail portions and integrally connect the two rail portions with one another,
wherein the two bending portions are deformed or bent transversely to the main axis so that the two rail portions are tilted towards one another by a predetermined or predeterminable bending angle, and/or
wherein the bending angle maximally amounts to 45°, and/or
wherein the bending angle minimally amounts to 5° or smaller than 5°,
wherein a width of the two bending portions which are oriented transversely with respect to the main axis, is smaller than a width of the two rail portions likewise oriented transversely with respect to the main axis, or
wherein a width of the two bending portions which are oriented transversely with respect to the main axis amounts to maximally 50% of a width of the two rail portions likewise oriented transversely with respect to the main axis, and/or
wherein a width of the two bending portions, which are oriented transversely with respect to the main axis, amounts to at least 25% of a width of the two rail portions likewise oriented transversely with respect to the main axis.

8. The diode carrier arrangement according to claim 7, wherein at least one of:
the at least one first diode receptacle is delimited or formed by a first flat rail portion of the first metal rail and by a first transverse support element of the enclosure,
wherein the first transverse support element elastically clamps the first diode inserted into the at least one first diode receptacle onto the first rail portion of the first metal rail,
the at least one second diode receptacle is delimited or formed by the at least one metal plate and by a second transverse support element of the enclosure, and
wherein the second transverse support element elastically clamps the second diode inserted into the at least one second diode receptacle onto the at least one metal plate.

9. The diode carrier arrangement according to claim 1, wherein:
the rail arrangement comprises a connection contact tab arranged on the first metal rail of the two metal rails, which is structured for soldering on or welding on a power supply conductor of an electric machine, and/or
the rail arrangement comprises a further connection contact tab arranged on the second metal rail of the two metal rails, which is structured for soldering on or welding on a neutral conductor of an electric machine, and
the connection contact tab and the further connection contact tab is arranged on two sides of the diode carrier arrangement that are opposite to one another.

10. The diode carrier arrangement according to claim 1, wherein at least one of:
the enclosure comprises fastening projections for fastening the diode carrier arrangement to an electric machine, and
wherein the fastening projections are each provided with a central opening for a fastener.

11. The diode carrier arrangement according to claim 1, wherein at lest one of:
the enclosure is composed of a thermoplastic material, and
the enclosure is composed of a thermoplastic material and a filling material.

12. The diode carrier arrangement according to claim 1, wherein at least one of:
the first metal rail and/or the second metal rail are structured as punched parts and/or are punched out of a thin conductive metal sheet,
the first metal rail and/or the second metal rail are composed of copper material, brass material, bronze material or other conductive metal materials,
the at least one metal plate is structured as a punched part and/or punched out of a thin conductive metal sheet, and
the at least one metal plate is composed of copper material, brass material, bronze material or other conductive metal materials.

13. An overvoltage protection device for an electric machine,
comprising:
at least one diode carrier arrangement, the at least one diode carrier arrangement including:
at least two diodes that are each equipped with a diode body and with at least one electrical connection contact pin arranged thereon for electrically contacting a respective diode and an electrical connection contact provided by the diode body or integrally formed with the diode body for electrically contacting a respective diode,
a rail arrangement including two separate electrically conductive metal rails,
at least one separate electrically conductive metal plate,
an enclosure arranged on the rail arrangement and the at least one metal plate for holding the rail arrangement and the at least one metal plate,
wherein the enclosure holds the at least one metal plate sandwich-like between the two metal rails so that the at least one metal plate does not directly touch the two metal rails and is flanked by the two metal rails,
at least one first diode receptacle delimited or formed by the enclosure and a first metal rail of the two metal rails for receiving a first diode of the at least two diodes and at least one second diode receptacle delimited or formed by the enclosure and the at least one metal plate for receiving a second diode of the at least two diodes,
wherein the first diode is inserted into the at least one first diode receptacle and is integrally connected with its at least one connection contact pin to the at least one metal plate in an electrically conductive manner and via the enclosure is clamped onto the first metal rail so that its connection contact is contacted to the first metal rail electrically and thermally conductively,
wherein the second diode is inserted into the at least one second diode receptacle, with its at least one connection contact pin integrally connected in an electrically conductive manner to a second metal rail of the two metal rails and via the enclosure is clamped onto the at least one metal plate so that its connection contact and/or its diode body is electrically contacted with the at least one metal plate in a thermally conductive manner,
wherein the at least two diodes of the diode carrier arrangement are configured for protecting the electrical machine from a supply voltage, which because of a fault rises above a rated voltage of the electric machine.

14. A motor vehicle component, comprising;
at least one overvoltage protection device according to claim 13 for an electric machine arranged within the motor vehicle component and electrically contacted with the same, or
at least one diode carrier arrangement according to claim 1 arranged within the motor vehicle component,
wherein the diode carrier arrangement is assembled with a protective cover of the motor vehicle component to form a subassembly,
wherein the diode carrier arrangement is pressed against the protective cover and fixed to the protective cover by clamping,
the protective cover further comprising a cover power supply conductor connector configured for serving as a power supply for the diode carrier arrangement and a cover neutral conductor connector configured for serving as a ground supply for the diode carrier arrangement,
wherein the subassembly is assembled to a main body of the motor vehicle component by a fastener, and
wherein the fastener goes through fastening projections of the diode carrier arrangement and fastening projections of the protective cover.

15. A manufacturing method for a diode carrier arrangement, comprising the steps:
providing a punched blank that comprises a first metal rail, a second metal rail and between the first metal rail and the second metal rail at least one metal plate, wherein the at least one metal plate is integrally connected to the first metal rail via installation aid ribs and is integrally connected to the second metal rail, of a metallic plate material by punching out,
adapting the metal rails to a predetermined contour of an electric machine by deforming or bending,
providing an enclosure for holding the metal rails and the at least one metal plate of a thermoplastic material and/or a filling material, and providing at least one first diode receptacle for receiving a first diode and at least one second diode receptacle for receiving a second diode, wherein the provided punched blank, forming or delimiting the at least one first diode receptacle and the at least one second diode receptacle, is over-moulded,
severing or cutting off of the installation aid ribs by punching,
inserting the first diode into the at least one first diode receptacle, so that the first diode is clamped onto the first metal rail by way of via the enclosure, so that it is electrically and thermally conductively contacted with the first metal rail, and electrically conductive integral connecting of at least one connection contact pin of the first diode with the at least one metal plate, and
inserting the second diode into the at least one second diode receptacle, so that the second diode is clamped via the enclosure onto the at least one metal plate so that it is electrically and thermally conductively contacted with the at least one metal plate, and electrically conductive integral connecting of at least one connection contact pin of the second diode with a second metal rail of the two metal rails.

16. The overvoltage protection device according to claim 13, wherein:
the at least one first diode receptacle and the at least one second diode receptacle are arranged on two sides of the diode carrier arrangement that are opposite to one another; or
the at least one first diode receptacle and the at least one second diode receptacle are arranged on one same side of two sides of the diode carrier arrangement that are opposite to one another.

17. The overvoltage protection device according to claim 13, wherein the at least one first diode receptacle and the at least one second diode receptacle are identical in size.

18. The overvoltage protection device according to claim 13, wherein:
the at least one first diode receptacle is arranged on a first plane;
the at least one second diode receptacle is arranged on a second plane; and
the first plane and the second plane are parallel to one another.

19. The overvoltage protection device according to claim 13, wherein the first diode arranged in the at least one first diode receptacle is electrically connected in series with the second diode arranged in the at least one second diode receptacle.

20. The diode carrier arrangement according to claim 1, wherein the enclosure is composed of polyamide 66 (PA66), butylene terephthalate (PBT), or polyethylene terephthalate (PET).
